(19) United States
(12) Patent Application Publication
(10) Pub. No.: US 2017/0125618 A1
(43) Pub. Date: May 4, 2017

(54) Forming method for acigs film at low temperature and manufacturing method for solar cell by using the forming method

(71) Applicant: KOREA INSTITUTE OF ENERGY RESEARCH, Daejeon (KR)

(72) Inventors: Kihwan Kim, Daejeon (KR); Jae-ho YUN, Daejeon (KR); Jun-Sik Cho, Daejeon (KR); Jihye Gwak, Daejeon (KR); Young-Joo EO, Daejeon (KR); Ara Cho, Daejeon (KR); Kyung Hoon Yoon, Daejeon (KR); Kee Shik Shin, Daejeon (KR); Sejin Ahn, Daejeon (KR); Joo-Hyung Park, Daejeon (KR); Seoung-Kyu Ahn, Daejeon (KR); Jin-su Yoo, Daejeon (KR)

(73) Assignee: KOREA INSTITUTE OF ENERGY RESEARCH, Daejeon (KR)

(21) Appl. No.: 14/757,521

(22) Filed: Dec. 23, 2015

(30) Foreign Application Priority Data
Oct. 30, 2015 (KR) 10-2015-0152424

(51) Int. Cl. H01L 31/032

(52) U.S. Cl. CPC H01L 31/0322

(57) ABSTRACT

Disclosed is a method of forming a CIGS-based thin film having high efficiency using a simple process at relatively low temperatures. The method includes an Ag thin film forming step and an ACIGS forming step of depositing Cu, In, Ga, and Se on the surface of the Ag thin film using a vacuum co-evaporation process. Ag, constituting the Ag thin film, is completely diffused, while Cu, In, Ga, and Se are deposited to form ACIGS together with Cu, In, Ga, and Se co-evaporated in a vacuum during the ACIGS forming step. The Ag thin film is formed and CIGS elements are then deposited using vacuum co-evaporation to form an ACIGS thin film having improved power generation efficiency at a relatively low temperature of 400° C. or less using only a single-stage vacuum co-evaporation process.

This research was financially supported by the Framework of the Research and Development Program of the Korea Institute of Energy Research (KIER) (Grant no. B5-2551), and the International Collaborative Energy Technology R&D Program of the Korea Institute of Energy Technology Evaluation and Planning under (financial source from the Ministry of Trade, Industry & Energy, Republic of Korea) (grant no.20138520011120).

### BACKGROUND OF THE INVENTION

1. Field of the Invention

The present invention relates to a method of forming a CIGS-based thin film applied to a light absorption layer of a solar cell and, more particularly, to a method of forming a CIGS-based thin film having excellent photoelectric conversion efficiency at relatively low temperatures.

2. Description of the Related Art

Recently, the importance of development of next-generation clean energy has grown owing to serious environmental pollution and the fossil energy depletion. Among the kinds of next generation clean energy, a solar cell is an apparatus that directly converts solar energy into electric energy. Solar cells cause almost no pollution, use an inexhaustible resource, and have a semipermanent lifespan, and accordingly, the solar cell is expected to be an energy source that solves future energy problems.

The solar cell is classified into various types according to the material that is used for the light absorption layer, and currently, a silicon solar cell, using silicon, is most frequently used. However, the price of silicon is currently skyrocketing owing to the short supply thereof, thus increasing interest in thin film-type solar cells. Thin film-type solar cells are manufactured to a small thickness to reduce material consumption and the weight thereof, thus widening the application scope thereof. CIGS (copper indium gallium selenide), which has a high light absorption coefficient, is in the spotlight as a material for the thin film-type solar cell. The reason is because CIGS is used as the light absorption layer of the thin film solar cell to thus attain high conversion efficiency.

A process of forming the CIGS light absorption layer has been developed to improve the efficiency of the light absorption layer, and representative examples include a vacuum co-evaporation process and a Se/S-based reaction process of a precursor thin film. For the vacuum co-evaporation process, elements constituting CIGS are co-evaporated to perform deposition. Recently, a three-stage vacuum co-evaporation process, in which co-deposited elements and temperatures are adjusted over three stages, has been mainly used (References: Korean Patent No. 10-0977529 and Korean Patent Application Laid-Open No. 10-2013-0007188). For the Se/S-based reaction process of the precursor thin film, a precursor film is made of elements other than Se or S and then heat-treated in a gas atmosphere including Se or S to perform selenization and sulfuration, thus forming CIGS.

However, the aforementioned processes have drawbacks in that processing is complicated, the processing time is relatively long and the processing temperature is high, thereby increasing processing costs, and in that the temperature exceeds 400° C. during the three-stage vacuum co-evaporation process or the selenization or sulfuration process, thereby limiting the substrates to which the process can be applied.

### SUMMARY OF THE INVENTION

Accordingly, the present invention has been made keeping in mind the above problems occurring in the related art, and an object of the present invention is to provide a method of forming a CIGS-based thin film having high efficiency using a simple process at relatively low temperatures.

In order to accomplish the above object, the present invention provides a method of forming an ACIGS thin film, including an Ag thin film forming step, and an ACIGS forming step of depositing Cu, In, Ga, and Se on the surface of the Ag thin film using a vacuum co-evaporation process. The Ag constituting the Ag thin film is completely diffused while Cu, In, Ga, and Se are deposited to form ACIGS together with Cu, In, Ga, and Se, which are co-evaporated in a vacuum during the ACIGS forming step.

An attempt to use ACIGS, formed by partially substituting Cu with Ag in the CIGS-based light absorption layer, as the light absorption layer has been conducted in the related art, and in particular there are cases of using ACIGS for the purpose of changing a band gap to manufacture a tandem solar cell.

The vacuum co-evaporation process may be performed using a single-stage CIGS vacuum co-evaporation process, and is preferably performed at a temperature ranging from 300 to 400° C.

In the present invention, a process of forming the ACIGS thin film may be improved to apply the relatively simpler single-stage vacuum co-evaporation process, and the ACIGS thin film having excellent efficiency may be formed at a relatively low temperature ranging from 300 to 400° C.

In addition, the thickness of the Ag thin film may be adjusted depending on the content of Ag included in the ACIGS thin film, which is the manufacturing target, and the content of Ag included in the ACIGS thin film may be in the range of 0.05 to 0.25 based on an Ag/(Ag+Cu) ratio.

In the present invention, since the process is performed in a relatively low temperature range, Ag is not uniformly dispersed when the content of Ag is very high, thus allowing the composition of the thin film to be non-uniform.

The Ag thin film forming step may be performed using a DC sputtering process. The Ag thin film forming process is not limited thereto, but DC sputtering is mainly used when a Mo electrode layer is formed as a rear side electrode of a CIGS-based solar cell, and accordingly, the same process is favorably applied.

A method of manufacturing a solar cell according to another embodiment of the present invention is provided to manufacture a solar cell including a CIGS-based light absorption layer, and the CIGS-based light absorption layer is manufactured using the process of forming the ACIGS thin film.

The present invention includes forming an ACIGS light absorption layer using a simple process at a relatively low temperature. A typical process of manufacturing a CIGS-based solar cell may be applied to the present invention without being limited other than the process of forming the light absorption layer, and thus details thereof will be omitted.

Na, which is included in a soda lime glass substrate, is diffused in a larger amount than other substrates into the light absorption layer when the method of forming the ACIGS thin film of the present invention is used, and accordingly, it is preferable to apply the soda lime glass substrate. However, the type of substrate that may be applied is not particularly limited, and the ACIGS thin film may be applied without limitation to any particular substrate, such as stainless steel or flexible substrates.

An ACIGS thin film according to another embodiment of the present invention is formed by partially substituting Cu with Ag in CIGS. Cu, In, Ga, and Se are deposited on the surface of an Ag thin film formed in advance using a vacuum co-evaporation process to completely diffuse Ag constituting the Ag thin film into a CIGS thin film formed using deposition during the vacuum co-evaporation process to thus substitute Cu with Ag, thereby forming the ACIGS thin film.

A small amount of Ag is further diffused during vacuum co-evaporation of the present invention to thus improve the crystallinity of the ACIGS thin film, thus attaining relatively large crystal grains and reducing surface voids.

The microstructure of the ACIGS thin film is an important characteristic that affects the improvement in efficiency of the solar cell, and is different from that of an existing ACIGS thin film. However, it is difficult to specifically express the characteristic numerically and the characteristic is drawn using the manufacturing method of the present invention, and accordingly, the microstructure characteristic is described using the manufacturing method to most precisely and clearly show the characteristic of the ACIGS thin film according to the present invention.

A solar cell according to the last embodiment of the present invention includes a CIGS-based light absorption layer. The CIGS-based light absorption layer is an ACIGS thin film, and Cu, In, Ga, and Se are deposited on the surface of an Ag thin film, formed in advance using a vacuum co-evaporation process, to completely diffuse Ag constituting the Ag thin film into a CIGS thin film formed using deposition during the vacuum co-evaporation process, to thus substitute Cu with Ag, thereby forming the ACIGS thin film. The constitution of the CIGS-based solar cell may be applied without any limitation, except that the solar cell of the present invention includes the ACIGS thin film as the light absorption layer, and thus details will be omitted.

The ACIGS thin film may have an Ag/(Ag+Cu) ratio ranging from 0.05 to 0.25. When the content of Ag is too low, the improvement in efficiency attributable to the Ag thin film is insignificant, and when the content of Ag is too high, the power generation efficiency of the solar cell is reduced, owing to the non-uniformity of the composition of the light absorption layer.

Further, when the ACIGS light absorption layer of the present invention is manufactured, the ACIGS light absorption layer includes Na, which is diffused from the soda lime glass substrate in a relatively larger amount than the other substrates, and accordingly, it is preferable to use the soda lime glass substrate. However, the type of substrate that may be applied is not particularly limited, and the ACIGS thin film may be applied without any limitation to various substrates, such as stainless steel and flexible substrates.

According to the present invention having the aforementioned constitution, the Ag thin film is formed and CIGS elements are then deposited using vacuum co-evaporation, thus allowing an ACIGS thin film having improved power generation efficiency to be formed at a relatively low temperature of 400° C. or lower, using only a single-stage vacuum co-evaporation process.

Further, the solar cell of the present invention includes the ACIGS thin film, the crystallinity of which is improved using a predetermined manufacturing method, as a light absorption layer to reduce surface voids and improve the orientation of grains, thus improving power generation efficiency.

Moreover, the solar cell of the present invention includes the ACIGS light absorption layer including Na, which is diffused from the soda lime glass substrate in a larger amount than that of other substrates using a unique manufacturing method, and accordingly, it is possible to provide a solar cell having improved power generation efficiency owing to the dispersion of Na.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 4 are electron microscopic pictures showing the photographed surface of a light absorption layer depending on the content of Ag;

FIGS. 5 to 8 are electron microscopic pictures showing a photographed section of the light absorption layer depending on the content of Ag;

FIG. 9 shows the XRD results of the light absorption layers depending on the content of Ag;

FIG. 10 shows XRD (112) patterns;

FIGS. 11 to 14 are SIMS profiles showing the measured distribution of Ag and Ga in the light absorption layer depending on the content of Ag;

FIG. 15 is SIMS profiles showing the measured distribution of Na in the light absorption layer depending on the content of Ag;

FIG. 16 shows J-V curves of solar cells manufactured using methods of the present examples and a comparative example;

FIG. 17 shows external quantum efficiency curves of the solar cells manufactured using the methods of the present examples and the comparative example;

FIG. 18 shows a measured open circuit voltage V, as a function of the content of Ag;

FIG. 19 shows a measured short-circuit current J, as a function of the content of Ag;

FIG. 20 shows a measured FF (fill factor) as a function of the content of Ag; and

FIG. 21 shows a measured conversion efficiency as a function of the content of Ag.

### DESCRIPTION OF THE PREFERRED EMBODIMENTS

Hereinafter, a detailed description will be given of embodiments of the present invention, with reference to the appended drawings.

In the method of manufacturing a solar cell according to the present example, a substrate is first prepared.

Various types of substrate are used for solar cells. However, a soda lime glass substrate is used and known as the substrate providing the highest efficiency of a CIGS solar cell, and has a thickness of 1 to 2 mm.

A Mo electrode layer is formed as a rear side electrode on the surface of the substrate. Mo is a material of the rear side electrode that is known to increase the efficiency of the CIGS solar cell, like the soda lime glass substrate, and the Mo electrode layer is formed to a thickness of 1 μm using a DC sputtering apparatus.

Next, an Ag thin film is formed on the surface of the Mo electrode layer. The Ag thin film is formed using the same DC sputtering apparatus as the Mo electrode layer. The Ag thin film is formed so as to have various thicknesses in the range of 100 to 360 nm, thus adjusting the content of Ag included in the ACIGS thin film, which is to be formed last.

The surface of the Ag thin film is subjected to a vacuum co-evaporation process using Cu, In, Ga, and Se sources. The process used to form a CIGS light absorption layer may be applied almost without change to the vacuum co-evaporation process. Particularly, in the present example, a single-stage vacuum co-evaporation process, simultaneously opening four sources, is applied instead of a three-stage vacuum co-evaporation process, which is frequently used to improve the efficiency of the CIGS light absorption layer, and accordingly, the vacuum co-evaporation process is performed while a chamber is maintained at a temperature of 350° C. Accordingly, the deposited light absorption layer has a thickness ranging from 2 to 3 μm.

In addition, a CdS layer, which is used as the buffer layer of the CIGS-based light absorption layer, is formed. The CdS layer is formed to a thickness of 60 nm using a chemical bath deposition process.

Next, a TCO layer is formed as a window layer on the surface of the CdS layer. ZnO is used as the material of the TCO layer, and two layers of an i-ZnO layer having a thickness of 50 nm and an n-ZnO layers having a thickness of 500 nm are formed.

Finally, a front side grid electrode of Al is formed to a thickness of 800 nm using a thermal evaporation process.

First, the characteristics of the light absorption layer that is formed using the deposition of Cu, In, Ga, and Se during the single-stage co-evaporation process after the Ag thin film is formed will be described.

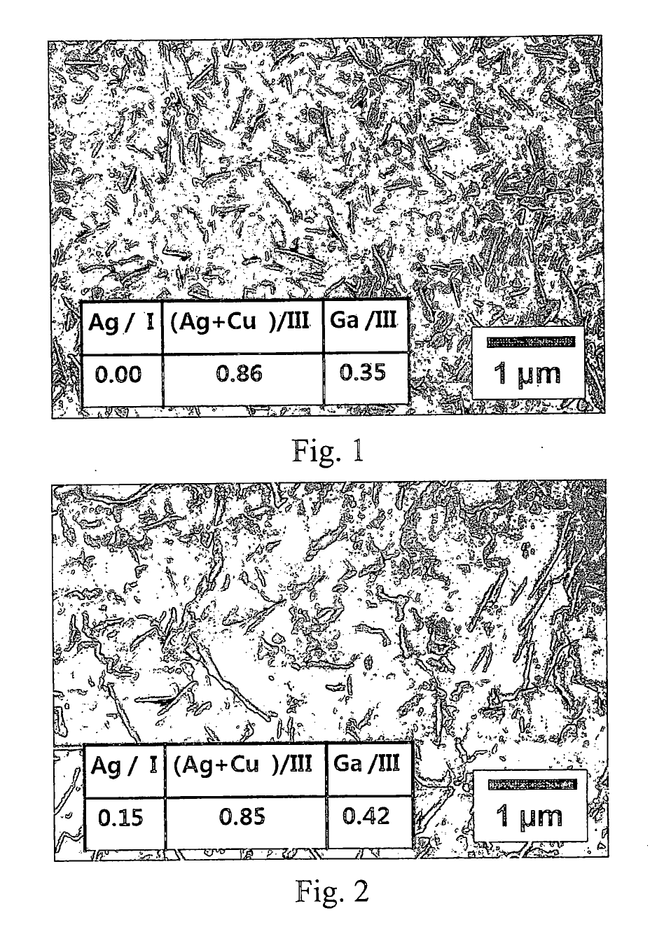

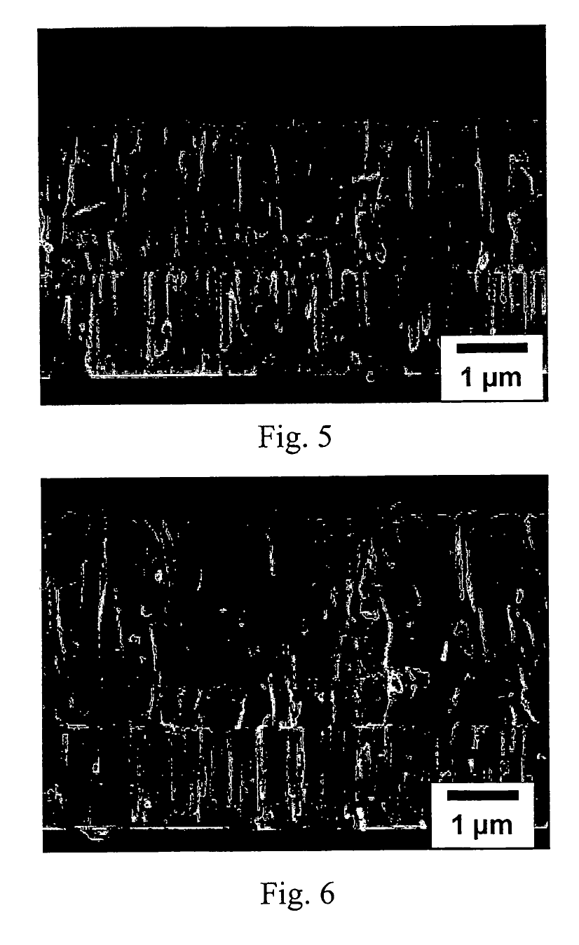

FIGS. 1 to 4 are electron microscopic pictures showing the photographed surface of the light absorption layer depending on the content of Ag, and FIGS. 5 to 8 are electron microscopic pictures showing the photographed section of the light absorption layer depending on the content of Ag.

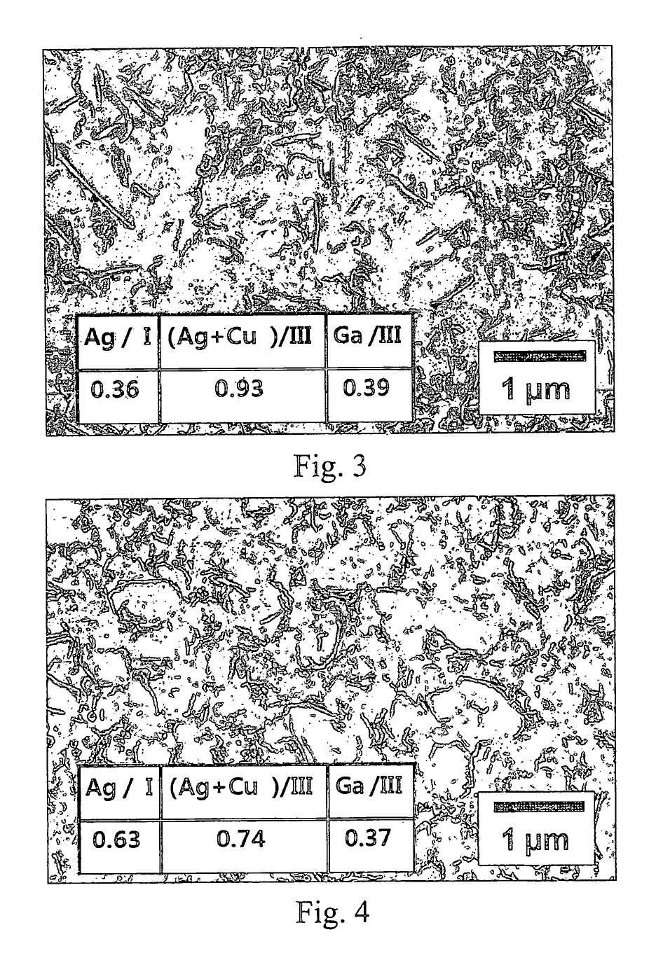

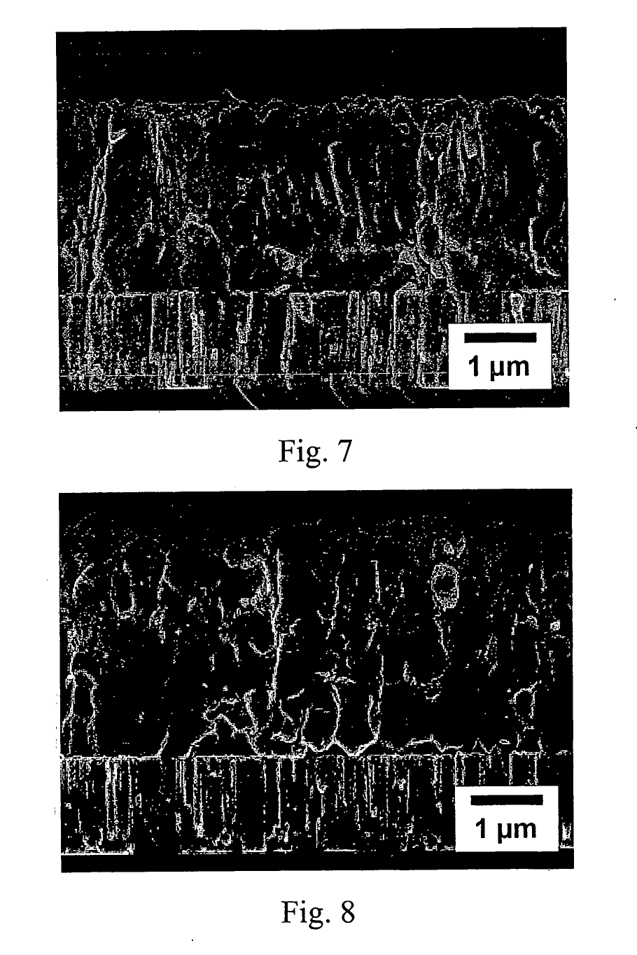

The content of Ag is calculated using an Ag/(Ag+Cu) ratio (unless the content of Ag is particularly specified otherwise), and FIGS. 1 and 5 show the case where the Ag thin film is not formed, meaning that no Ag is present (the Ag/(Ag+Cu) ratio is 0). FIGS. 2 and 6 show the case where the Ag/(Ag+Cu) ratio is 0.15, FIGS. 3 and 7 show the case where the Ag/(Ag+Cu) ratio is 0.36, and FIGS. 4 and 8 show the case where the Ag/(Ag+Cu) ratio is 0.63.

From the drawings, it can be confirmed that a very fine crystalline CIGS light absorption layer is formed when the single-stage CIGS vacuum co-evaporation process is performed while the Ag thin film is not formed. On the other hand, from the pictures showing the surfaces, it can be confirmed that the size of the grain is increased to thus reduce surface voids when the Ag thin film is formed in advance. From the aforementioned description, it can be seen that the crystallinity of the light absorption layer is improved owing to the Ag thin film.

Meanwhile, from the pictures of the section of the light absorption layer, showing that the light absorption layer is positioned directly on the surface of the Mo electrode layer at a lower side because the Ag thin film is completely dispersed into the light absorption layer formed using the vacuum co-evaporation process, it can be seen that the light absorption layers of FIGS. 2 to 4 and 6 to 8 are the ACIGS thin film.

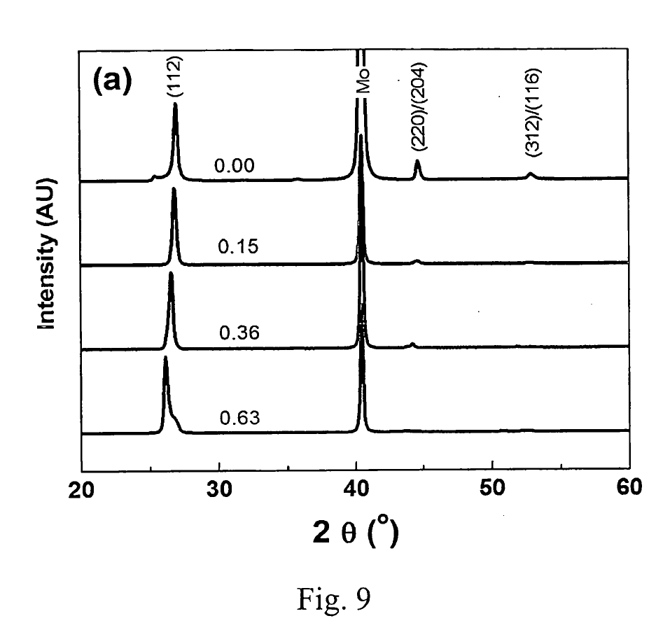

FIG. 9 shows the XRD results of the light absorption layers depending on the content of Ag.

Ag is included to decrease the peaks (220)/(204) and (312)/(116) shown in the light absorption layer, not including Ag, and to allow a strong peak (112) to remain, and accordingly, it can be confirmed that Ag is added to improve preferred orientation toward the (112) surface as the CIGS intrinsic peak.

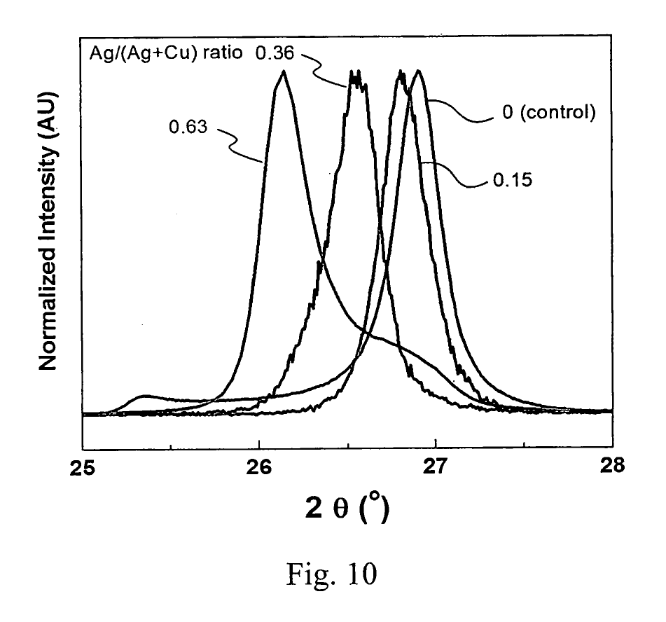

FIG. 10 shows XRD (112) patterns.

FIG. 10 shows that the peak (112) moves to the left as the content of Ag is increased, and it is considered that this is because Ag is added to increase the mobility of ions.

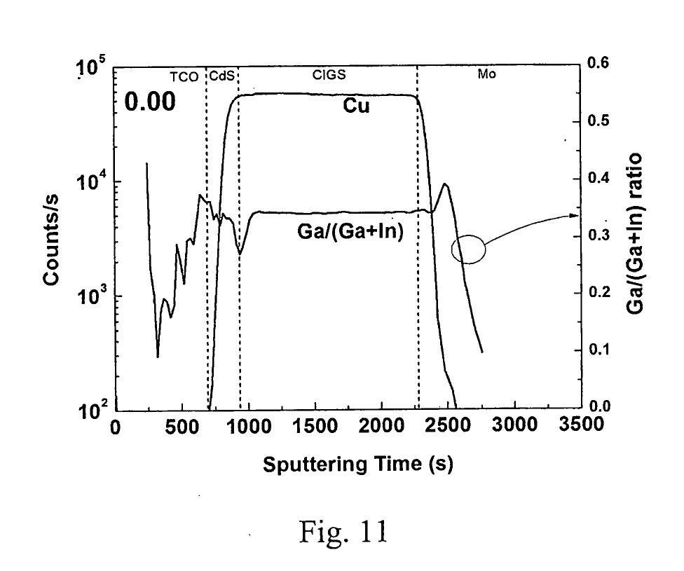

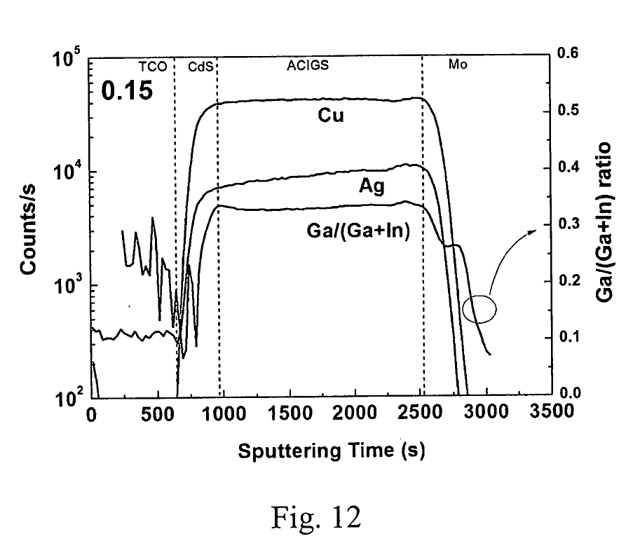

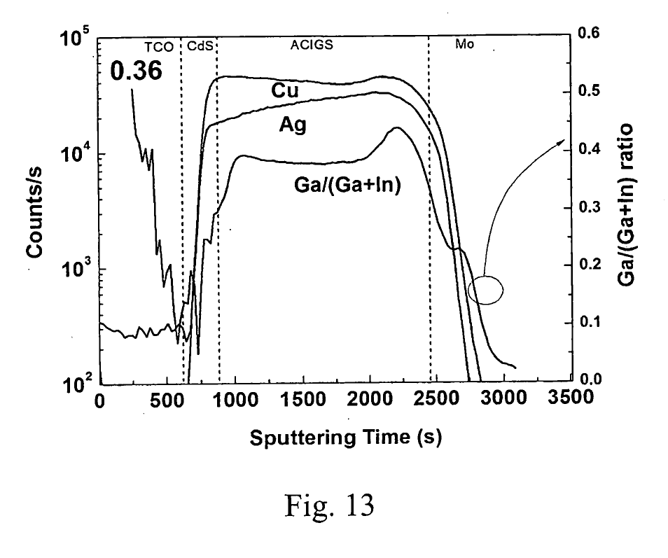

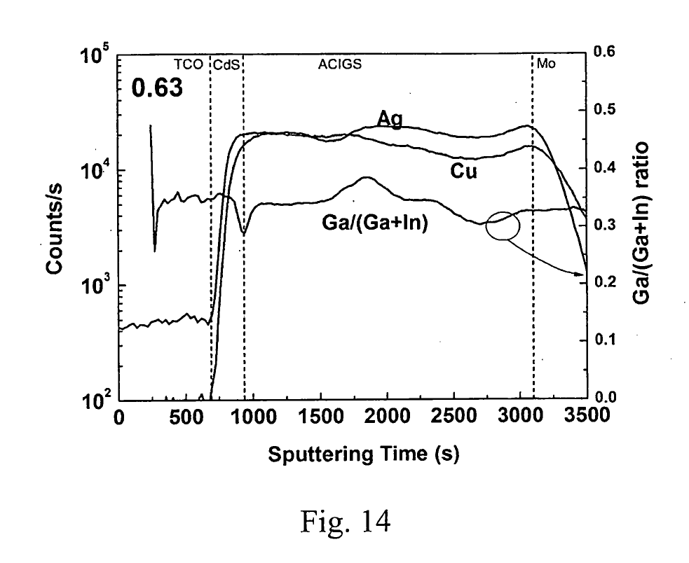

FIGS. 11 to 14 are SIMS profiles showing the measured distribution of Ag and Ga in the light absorption layer depending on the content of Ag.

The composition distribution of the light absorption layer that is formed can be confirmed using the SIMS (secondary ion mass spectroscopy) profile. Since Ag is not quantified, Ag is shown in the form of “counts/s” on the Y axis together with Cu, and Ga/III is shown on the right side.

When the content of Ag is relatively low, namely 0.15, there is an insignificant composition gradient and thus the formed ACIGS thin film is considered to be entirely uniform. However, when the content of Ag is high, a non-uniform composition gradient is shown, and it is considered that this is because Ag, constituting the Ag thin film formed in advance, is insufficiently diffused. A process for increasing the temperature of the chamber during the vacuum co-evaporation process may be considered in order to solve the aforementioned non-uniform composition gradient, and should be based on total process efficiency. According to the present example, when the content of Ag is 0.36 or more, the Ag composition is non-uniform, and accordingly, the Ag thin film may be formed in a content that is lower than 0.36. From additional experimentation, it can be confirmed that an ACIGS thin film having no composition gradient problem is manufactured even at a temperature of 400° C. or less when the Ag/(Ag+Cu) ratio is in the range of 0.05 to 0.25.

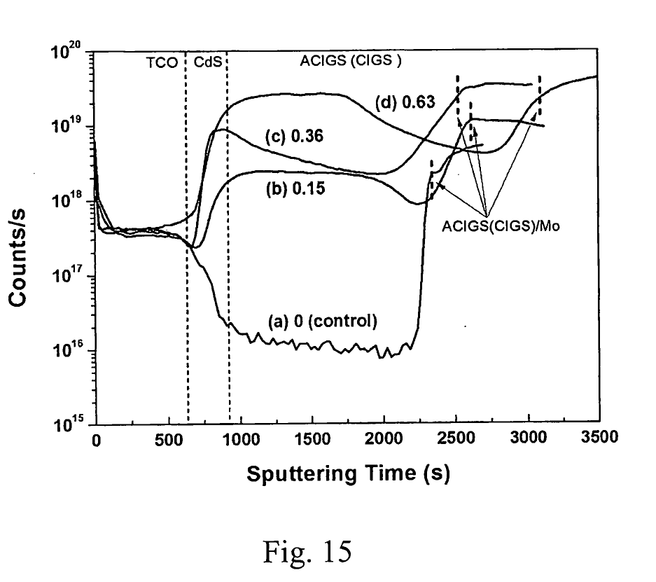

FIG. 15 is a SIMS profile showing the measured distribution of Na in the light absorption layer depending on the content of Ag.

As described above, the CIGS solar cell has excellent photoelectric conversion efficiency when using a soda lime glass substrate, and it is known that this is because Na included in the substrate is diffused to thus be distributed in the light absorption layer during the manufacturing process.

From the drawings, it can be confirmed that Na is distributed in the light absorption layer in a larger amount when the Ag thin film is formed in advance according to the present example than when the Ag thin film is not formed. This means that when the method of the present example is applied, the amount of Na that diffuses into the light absorption layer is increased to further improve the efficiency realized by the use of the soda lime glass substrate.

The photovoltage characteristics of the solar cells manufactured using the manufacturing methods of the present examples and the comparative example will be described hereinafter.

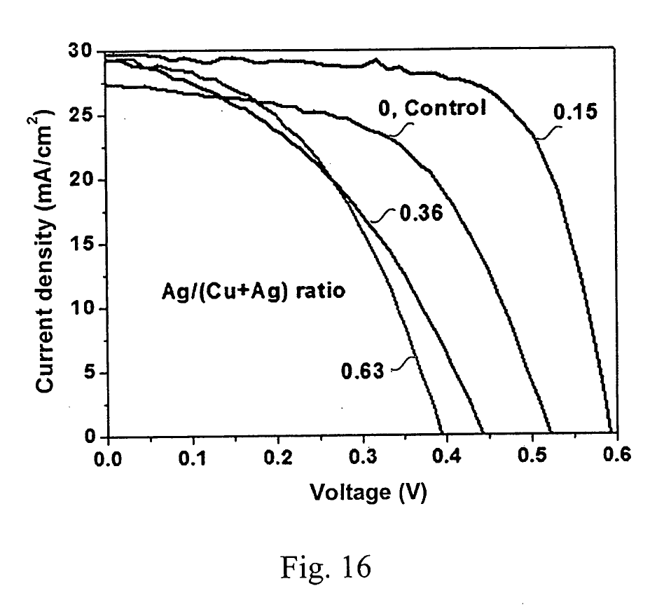

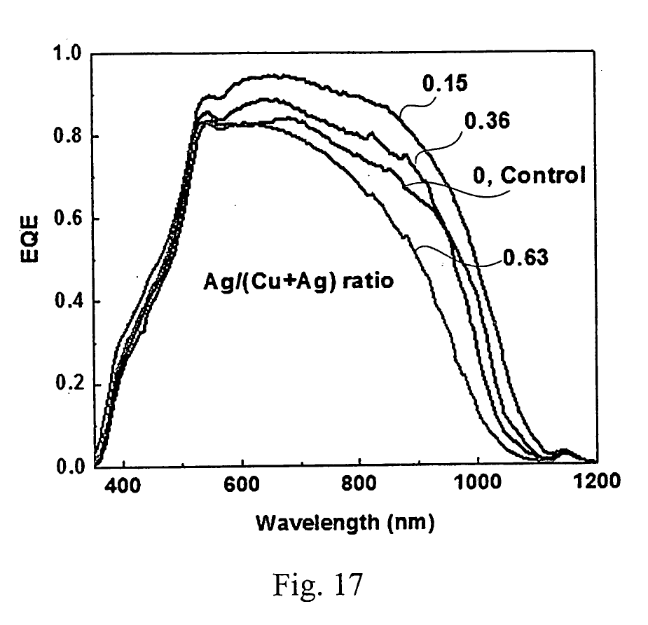

FIG. 16 shows J-V curves of the solar cells manufactured using the methods of the present examples and the comparative example, and FIG. 17 shows external quantum efficiency curves of the solar cells manufactured using the methods of the present examples and the comparative example.

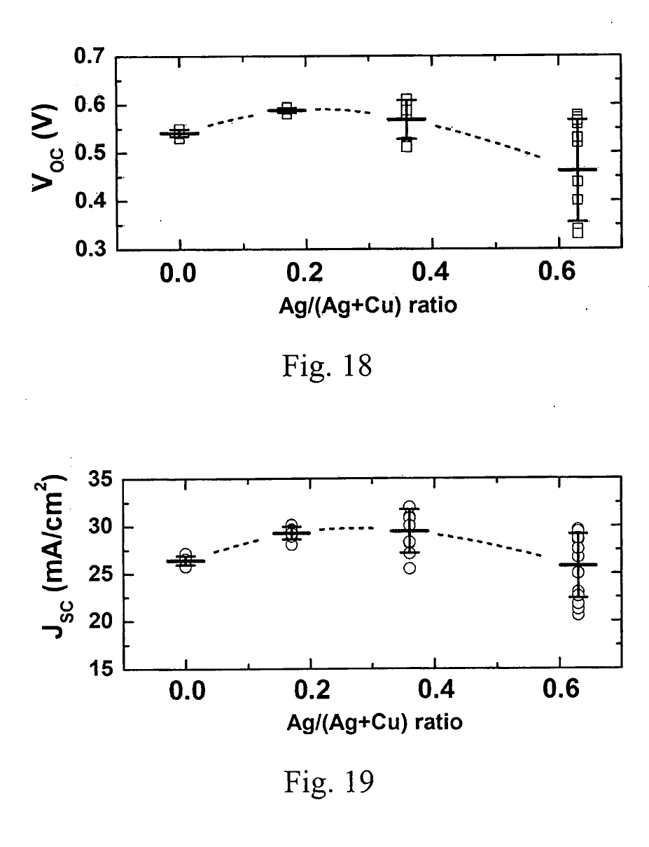

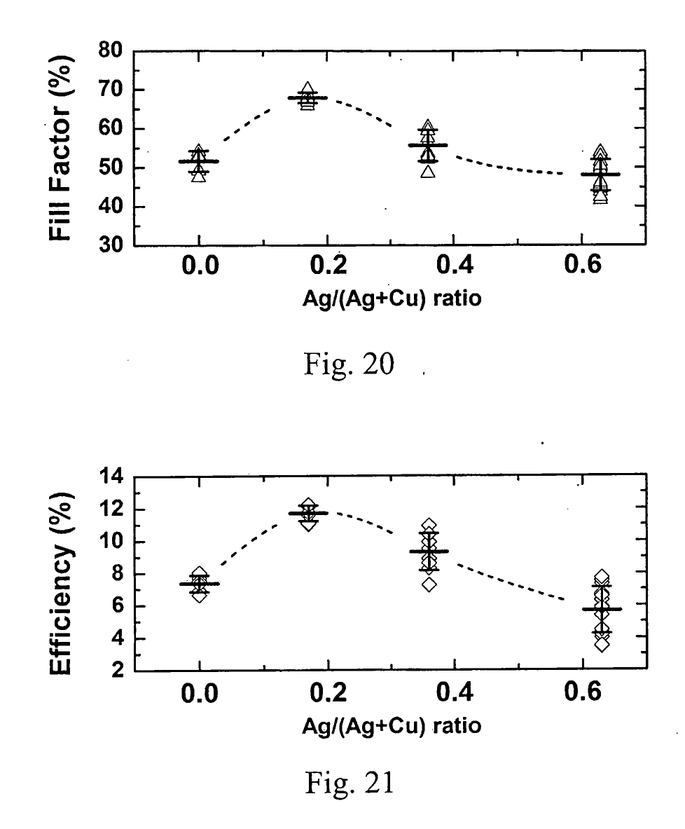

FIGS. 18 to 21 show a measured open circuit voltage V_{oc}, a short-circuit current J_{sc}, an FF (fill factor), and conversion efficiency as a function of the content of Ag.

The measured values of FIGS. 18 to 21 are described in the following Table 1.

TABLE 1

| Sample, | | | Fill | |
|---|---|---|---|---|
| Ag/(Ag + Cu) | V_{OC}, | J_{SC}, | Factor, | Efficiency, |
| ratio | V | mA/cm² | % | % |
| 0 | 0.522 | 27.1 | 54.5 | 8.5 |
| 0.15 | 0.590 | 29.7 | 68.9 | 12.1 |
| 0.36 | 0.442 | 29.2 | 40.9 | 5.3 |
| 0.63 | 0.395 | 29.4 | 46.1 | 5.4 |

As shown in the drawings and the table, photoelectric conversion efficiency is improved when the content of Ag is 0.15 compared to the comparative example, in which no Ag thin film is formed, but the efficiency is reduced when the content of Ag is 0.36 and 0.63.

It is considered that this is because the open circuit voltage is reduced in connection with the aforementioned non-uniform composition of the thin film when the content of Ag is high.

From the test result of the performance of the solar cell, it can be confirmed that when the Ag/(Ag+Cu) ratio, which indicates the content of Ag, is in the range of 0.05 to 0.25, the CIGS-based light absorption layer having improved efficiency is formed simply using the single-stage vacuum co-evaporation process at a temperature of 400° C. or less.

It can be confirmed that even though the ACIGS thin film manufactured in the example of the present invention is deposited using the simple single-stage vacuum co-evaporation process at a relatively low temperature of 350° C., the crystal growth property is improved due to the Ag thin film formed in advance to enlarge the crystal grains and thus reduce surface voids, a preferred orientation is improved toward the intrinsic (112) surface of CIGS, and Na diffused from the soda lime glass substrate is included in a large amount.

It is considered that the aforementioned results positively affect an improvement in photoelectric conversion efficiency when ACIGS is used as the light absorption layer. In practice, the solar cell manufactured in the example of the present invention has improved efficiency compared to the solar cell including the CIGS light absorption layer formed using the single-stage vacuum co-evaporation process.

Therefore, the method of forming the ACIGS thin film, the method of manufacturing the solar cell, and the solar cell manufactured using the same according to the present invention provide a solar cell having excellent efficiency at low processing cost. Moreover, since the process temperature is low, the range of substrates that are usable is widened. Accordingly, it is expected that the purpose of the ACIGS thin film is capable of being further expanded using various substrates.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of forming an ACIGS thin film, comprising:
an Ag thin film forming step; and
an ACIGS forming step of depositing Cu, In, Ga, and Se on a surface of the Ag thin film using a vacuum co-evaporation process,
wherein Ag, constituting the Ag thin film is completely diffused, while Cu, In, Ga, and Se are deposited to form ACIGS together with Cu, In, Ga, and Se, which are co-evaporated in a vacuum during the ACIGS forming step.

2. The method of claim 1, wherein the vacuum co-evaporation process is performed using a single-stage CIGS vacuum co-evaporation process.

3. The method of claim 1, wherein the ACIGS forming step is performed at a temperature ranging from 300 to 400° C.

4. The method of claim 1, wherein the Ag thin film has a thickness adjusted according to a content of Ag included in the ACIGS thin film, which is a manufacturing target.

5. The method of claim 4, wherein the content of Ag included in the ACIGS thin film as the manufacturing target is in a range of 0.05 to 0.25 based on an Ag/(Ag+Cu) ratio.

6. The method of claim 1, wherein the Ag thin film forming step is performed using a DC sputtering process.

7. An ACIGS thin film formed by partially substituting Cu with Ag in CIGS, wherein Cu, In, Ga, and Se are deposited on a surface of an Ag thin film formed in advance using a vacuum co-evaporation process to completely diffuse Ag constituting the Ag thin film into a CIGS thin film, formed using deposition during the vacuum co-evaporation process, and to substitute Cu with Ag.

8. The ACIGS thin film of claim 7, wherein the ACIGS thin film is used as a CIGS-based light absorption layer of a solar cell including the CIGS-based light absorption layer.

9. The ACIGS thin film of claim 8, wherein the ACIGS thin film has an Ag/(Ag+Cu) ratio ranging from 0.05 to 0.25.

10. The ACIGS thin film of claim 8, wherein the solar cell is formed on a soda lime glass substrate.
